(19) United States
(12) Patent Application Publication
(10) Pub. No.: US 2026/0096296 A1
(43) Pub. Date: Apr. 2, 2026

(54) DISPLAY PANEL AND DISPLAY APPARATUS

(71) Applicant: HKC CORPORATION LIMITED, SHENZHEN (CN)

(72) Inventors: Yao LI, SHENZHEN (CN); Pei XU, SHENZHEN (CN)

(73) Assignee: HKC CORPORATION LIMITED, SHENZHEN (CN)

(21) Appl. No.: 19/325,537

(22) Filed: Sep. 11, 2025

(30) Foreign Application Priority Data
Sep. 30, 2024 (CN) 202411391079.5

(51) Int. Cl. H10K 59/122; H10K 59/123; H10K 59/40

(52) U.S. Cl. CPC H10K 59/122; H10K 59/123; H10K 59/40

(57) ABSTRACT

A display panel and a display apparatus may be provided. The display panel may include a glass substrate, a pixel definition layer, light-emitting units, a touch-sensitive electrode, first bonding portions, second bonding portions, and a silicon-based driving substrate. The glass substrate may include a plurality of conductive vias. The plurality of conductive vias may include a plurality of first conductive vias and a plurality of second conductive vias. A first bonding portion may be electrically connected to a matched anode electrode through a first conductive via. A second bonding portion may be electrically connected to the touch-sensitive electrode through a second conductive via. The silicon-based driving substrate may include first bonding electrodes and second bonding electrodes. The first bonding electrodes may be aligned and bonded with the first bonding portions. The second bonding electrodes may be aligned and bonded with the second bonding portions.

### CROSS REFERENCE TO RELATED APPLICATIONS

This application claims priority to Chinese Patent Application No. 202411391079.5, filed on Sep. 30, 2024, which is herein incorporated by reference in its entirety.

### TECHNICAL FIELD

The present disclosure relates to a field of display technologies, and more particular to a display panel and a display apparatus.

### BACKGROUND

A monocrystalline silicon driving backplane is a driving substrate formed with semiconductor devices as driving units, and the semiconductor devices are fabricated by complementary metal oxide semiconductor (CMOS) process. Compared with conventional active-matrix organic light-emitting diode (AMOLED) panels that adopt amorphous silicon, micro-crystalline silicon, or low-temperature poly-silicon thin-film transistors as backplanes, the monocrystalline silicon driving backplane may have a much higher carrier mobility. Therefore, the organic light emitting diode (OLED) display panel based on silicon is currently a type of display panel with the best performance in products of augmented reality (AR) and/or virtual reality (VR) fields.

At present, display chips that are traditionally externally bonded are integrated into a silicon-based driving backplane in silicon-based OLED display panels. A preparation method may include fabricating OLED light-emitting devices by evaporation on a silicon-based driving substrate. The specific process may include: first depositing and forming an anode electrode, then fabricating a pixel definition layer, and then depositing an organic light-emitting layer and a cathode electrode in sequence. In this way, pixel units of smaller sizes may be prepared, thereby achieving display fineness beyond a retina level, and pixel units may include many advantages such as high resolution, high integration, low power consumption, small size, and light weight or the like.

However, directly fabricating the OLED light-emitting devices by evaporation on the silicon-based driving substrate may easily affect a silicon-based driving circuit, leading to damage of the driving circuit and making it unusable, which may increase the cost.

### SUMMARY

A technical solution adopted by the present disclosure is to provide a display panel. The display panel may include: a glass substrate, a pixel definition layer, a plurality of light-emitting units, a touch-sensitive electrode, a plurality of first bonding portions, a plurality of second bonding portions, and a silicon-based driving substrate. The glass substrate may include a first surface and a second surface that are opposite to each other. The glass substrate may define a plurality of conductive vias extending from the first surface to the second surface. The plurality of conductive vias may include a plurality of first conductive vias and a plurality of second conductive vias. The pixel definition layer may be arranged on the first surface of the glass substrate. The pixel definition layer may protrude from the glass substrate and enclose to form a pixel accommodation region. The plurality of light-emitting units may be arranged within the pixel accommodation region. A light-emitting unit may include an anode electrode, an organic light-emitting layer, and a cathode electrode that are stacked in sequence in a direction away from the glass substrate. The touch-sensitive electrode may be configured to cover the plurality of light-emitting units and the pixel definition layer. Each of the plurality of first bonding portions may be arranged in a matched first conductive via. Each of the plurality of first bonding portions may be electrically connected to a matched anode electrode through a matched first conductive via. Each of the plurality of second bonding portions may be arranged in a matched second conductive via. Each of the plurality of second bonding portions may be electrically connected to the touch-sensitive electrode through a matched second conductive via. The silicon-based driving substrate may be arranged on one side of the second surface of the glass substrate, and may include a plurality of first bonding electrodes and a plurality of second bonding electrodes. The plurality of first bonding electrodes may be aligned and bonded with the plurality of first bonding portions in one-to-one correspondence. The plurality of second bonding electrodes may be aligned and bonded with the plurality of second bonding portions in one-to-one correspondence. A projection of the second conductive via onto the glass substrate along a stacking direction of the display panel is located within a projection of the pixel definition layer onto the glass substrate along the stacking direction.

A technical solution adopted by the present disclosure is to provide a display apparatus. The display apparatus may include a display panel. The display panel may include: a glass substrate, a pixel definition layer, a plurality of light-emitting units, a touch-sensitive electrode, a plurality of first bonding portions, a plurality of second bonding portions, and a silicon-based driving substrate. The glass substrate may include a first surface and a second surface that are opposite to each other. The glass substrate may define a plurality of conductive vias extending from the first surface to the second surface. The plurality of conductive vias may include a plurality of first conductive vias and a plurality of second conductive vias. The pixel definition layer may be arranged on the first surface of the glass substrate. The pixel definition layer may protrude from the glass substrate and enclose to form a pixel accommodation region. The plurality of light-emitting units may be arranged within the pixel accommodation region. A light-emitting unit may include an anode electrode, an organic light-emitting layer, and a cathode electrode that are stacked in sequence in a direction away from the glass substrate. The touch-sensitive electrode may be configured to cover the plurality of light-emitting units and the pixel definition layer. Each of the plurality of first bonding portions may be arranged in a matched first conductive via. Each of the plurality of first bonding portions may be electrically connected to a matched anode electrode through a matched first conductive via. Each of the plurality of second bonding portions may be arranged in a matched second conductive via. Each of the plurality of second bonding portions may be electrically connected to the touch-sensitive electrode through a matched second conductive via. The silicon-based driving substrate may be arranged on one side of the second surface of the glass substrate, and may include a plurality of first bonding electrodes and a plurality of second bonding electrodes. The plurality of first bonding electrodes may be aligned and bonded with the plurality of first bonding portions in one-to-one correspondence. The plurality of second bonding electrodes may be aligned and bonded with the plurality of second bonding portions in one-to-one correspondence. A projection of the second conductive via onto the glass substrate along a stacking direction of the display panel is located within a projection of the pixel definition layer onto the glass substrate along the stacking direction.

### BRIEF DESCRIPTION OF THE DRAWINGS

FIG. 1a is a schematic structural diagram of a first embodiment of a display panel according to the present disclosure.

FIG. 1b is a sectional view along a A-A line of the display panel in FIG. 1a.

FIG. 2 is a top view of the display panel in FIG. 1a.

FIG. 3 is a schematic structural diagram of a second embodiment of a display panel according to the present disclosure.

FIG. 4 is a schematic structural diagram of a display apparatus according to an embodiment of the present disclosure.

### DETAILED DESCRIPTION

Technical solutions in embodiments of the present disclosure will be described clearly and thoroughly in connection with accompanying drawing of the embodiments of the present disclosure. Obviously, the described embodiments are only a part of the embodiments, but not all of them. All other embodiments by a person of ordinary skills in the art based on embodiments of the present disclosure without creative efforts should all be within the protection scope of the present disclosure.

The terms “first”, “second”, and “third” in the present disclosure are only for the purpose of description, and cannot be construed as indicating or implying relative importance or implicitly indicating the number of technical features referred to. Therefore, the features defined with “first”, “second”, and “third” may explicitly or implicitly include at least one of the features. In the description of the present disclosure, “a plurality of” means at least two, such as two, three, etc., unless otherwise specifically defined. All directional indicators (such as up, down, left, right, front, back . . . ) in embodiments of the present disclosure are only used to explain a motion state, a relative positional relationship between the components in a specific posture (as shown in the drawings). If the specific posture changes, then the directional indication will change accordingly. In addition, the terms “include”, “comprise” and any variations thereof are intended to cover non-exclusive inclusion. For example, a process, a method, a system, a product, or a device that includes a series of operations or units is not limited to the listed operations or units, but optionally includes unlisted operations or units, or optionally also includes other operations or units inherent to these processes, methods, products or devices.

Reference to “embodiments” herein means that a specific feature, structure, or characteristic described in conjunction with the embodiments may be included in at least one embodiment of the present disclosure. The appearance of this phrase in various locations in the specification does not necessarily refer to the same embodiment, nor is it an independent or alternative embodiment mutually exclusive with other embodiments. Those skilled in the art may explicitly and implicitly understand that, the embodiments described herein may be combined with other embodiments.

The present disclosure will be described in detail below with reference to the drawings and embodiments.

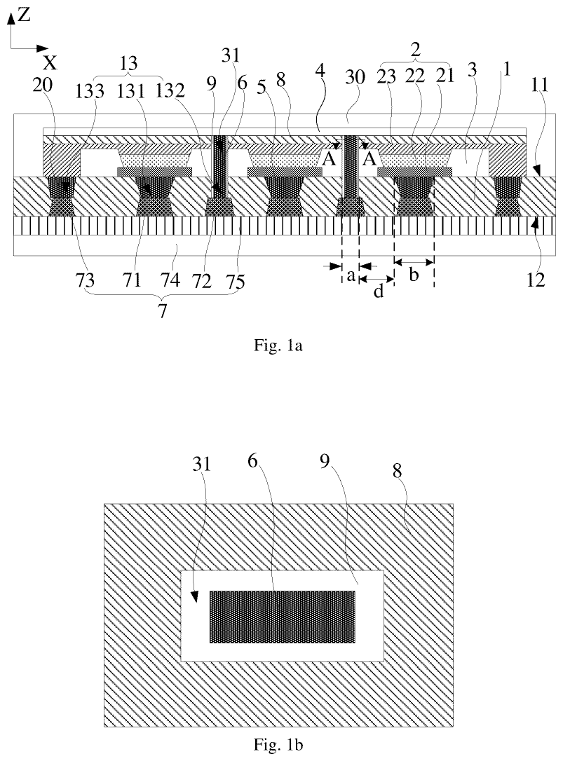

As illustrated in FIG. 1a, FIG. 1a is a schematic structural diagram of a first embodiment of a display panel according to the present disclosure. The present disclosure provides a display panel. The display panel may be an OLED display panel. The display panel may include a glass substrate 1, a plurality of light-emitting units 2, a plurality of first bonding portions 5, and a silicon-based driving substrate 7.

The glass substrate 1 may include a first surface 11 and a second surface 12 that are opposite to each other. The glass substrate 1 may include a plurality of conductive vias 13 extending from the first surface 11 to the second surface 12. The plurality of conductive vias 13 may include a plurality of first conductive vias 131 and a plurality of second conductive vias 132.

A pixel definition layer 3 may be further arranged on the first surface 11 of the glass substrate 1. The pixel definition layer 3 may protrude from the glass substrate 1 and enclose a plurality of pixel accommodation regions (not illustrated in the drawings). The plurality of light-emitting units 2 may be respectively arranged within the plurality of pixel accommodation regions. The plurality of pixel accommodation regions may be arranged in one-to-one correspondence with the plurality of first conductive vias 131. The plurality of second conductive vias 132 may be arranged matching with part of the pixel definition layer 3. In other words, the plurality of first conductive vias 131 may be arranged at locations of the glass substrate 1 matching with the plurality of pixel accommodation regions. The plurality of second conductive vias 132 may be arranged at locations of the glass substrate 1 matching with part of the pixel definition layer 3.

Specifically, a projection of a first conductive via 131 onto the glass substrate 1 along a stacking direction Z of the display panel may be located within a projection of the pixel accommodation region onto the glass substrate 1 along the stacking direction Z. A projection of a second conductive via 132 onto the glass substrate 1 along the stacking direction Z may be located within a projection of the pixel definition layer 3 onto the glass substrate 1 along the stacking direction Z.

The plurality of light-emitting units 2 may be arranged on the first surface 11 of the glass substrate 1. Each light-emitting unit 2 may include an anode electrode 21, an organic light-emitting layer 22, and a cathode electrode 23 that are stacked in sequence in a direction away from the glass substrate 1. The anode electrode 21 may be arranged on the surface of the glass substrate 1 exposed through the pixel accommodation region. The pixel definition layer 3 may cover an edge of the anode electrode 21. This is to avoid a contact between the anode electrodes 21 of adjacent light-emitting units 2, such a contact may cause a case of signal crosstalk. The organic light-emitting layer 22 may be arranged on a side surface of the anode electrode 21 away from the glass substrate 1. The cathode electrode 23 may be arranged on a side of the organic light-emitting layer 22 away from the anode electrode 21 and cover the organic light-emitting layers 22 of the plurality of light-emitting units 2. The anode electrode 21 may transmit an anode drive signal to the organic light-emitting layer 22, and the cathode electrode 23 may transmit a cathode drive signal to the organic light-emitting layer 22, so as to drive the organic light-emitting layer 22 to emit light.

In some embodiments, the light-emitting units 2 may include light-emitting units with different emission colors, such as red light-emitting units, green light-emitting units, and blue light-emitting units, so as to achieve colorful display. Specifically, an emission color of the light-emitting unit 2 may be determined by an emission color of the organic light-emitting layer 22. Alternatively, in some other embodiments, the light-emitting units 2 may also be light-emitting units of a same color, such as white, red, green, blue, or other colors, which may be specifically set according to actual needs. For example, if the light-emitting unit 2 is white, grayscale display may be achieved by controlling a brightness of the light-emitting unit 2. A color resistant layer may be additionally provided above the light-emitting unit 2, so as to achieve colorful display. For example, if the light-emitting units 2 are blue, a red quantum dot layer may be additionally arranged above some of the light-emitting units 2, and a green quantum dot layer may be additionally arranged above some of the light-emitting units 2, so as to achieve colorful display.

Each first bonding portion 5 may be at least partially arranged in a matched first conductive via 131. Each first bonding portion 5 may be electrically connected to the matched anode electrode 21 through the first conductive via 131, so as to transmit an anode drive signal to the anode electrode 21 of the matched light-emitting unit 2 through the first conductive via 131.

A plurality of second bonding portions 6 may be arranged on the second surface 12 of the glass substrate 1, and each second bonding portion 6 may be at least partially arranged in the matched second conductive via 132. Each second bonding portion 6 may be electrically connected to a touch-sensitive electrode 4 through the second conductive via 132, thereby enabling the touch-sensitive electrode 4 to transmit a touch-controlling signal through the second conductive via 132.

The silicon-based driving substrate 7 may be arranged on one side of the second surface 12 of the glass substrate 1. The silicon-based driving substrate 7 may further include a plurality of first bonding electrodes 71 and a plurality of second bonding electrodes 72. The plurality of first bonding electrodes 71 may be aligned and bonded with the plurality of first bonding portions 5 in one-to-one correspondence, so as to control light emission of the light-emitting units 2 matching with the first bonding portions 5. The plurality of second bonding electrodes 72 may be aligned and bonded with the plurality of second bonding portions 6 in one-to-one correspondence, so as to transmit the touch-controlling signal. Specifically, the silicon-based driving substrate 7 may further include a silicon base substrate 74 and a driving circuit 75 arranged in a stacked manner. The silicon base substrate 74 may refer to a base substrate plate of a monocrystalline silicon material. The driving circuit 75 may be electrically connected to the plurality of first bonding electrodes 71, so as to transmit the anode drive signal to the anode electrode 21 through the first bonding portions 5. Specifically, the driving circuit 75 may include an active driving circuit integrated on a monocrystalline silicon base substrate through a complementary metal-oxide-semiconductor (CMOS) process. The driving circuit 75 may include a plurality of “3T1C” (3 thin-film transistors and 1 capacitor) structure, so as to achieve independent control of each light-emitting unit 2 and a high-quality image display.

The silicon-based driving substrate 7 may further include a display control circuit (not illustrated in the drawings). The display control circuit may be electrically connected to the driving circuit 75. The display control circuit may control the light-emitting units 2 to perform display through the driving circuit 75. The display control circuit may be an integrated circuit (IC) integrated on the silicon-based driving substrate 7.

By arranging the light-emitting units 2 and the first bonding portions 5 on the two opposite surfaces of the glass substrate 1 respectively, the plurality of first bonding portions 5 may be in contact and electrically connected to the anode electrodes 21 of the matched light-emitting units 2 through the first conductive vias 131. After the first bonding portions 5 are bonded to the first bonding electrode 71 of the silicon-based driving substrate 7, an electrical coupling between the light-emitting units 2 and the silicon-based driving substrate 7 may be achieved, enabling the silicon-based driving substrate 7 to drive the light-emitting units 2 to emit light. In this way, the light-emitting units 2 may be fabricated on the glass substrate 1 and then bonded to the silicon-based driving substrate 7. There is no need to directly fabricate the light-emitting units 2 on the silicon-based driving substrate 7, the problem of reduced product yield caused by damage to the pixel driving circuit 75 due to directly fabrication of the light-emitting units 2 on the silicon-based driving substrate 7 may be avoided. By covering the light-emitting unit 2 with the touch-sensitive electrode 4 and arranging the second conductive vias 132 at locations of the glass substrate 1 matching with the pixel definition layer 3, the plurality of second bonding portions 6 may be respectively electrically connected to the matched touch-sensitive electrodes 4 through the second conductive vias 132. After the second bonding portions 6 are bonded to the second bonding electrodes 72, electrical coupling between the touch-sensitive electrodes 4 and the silicon-based driving substrate 7 may be achieved, thereby enabling the touch-sensitive electrodes 4 to transmit the touch-controlling signal to and from the silicon-based driving substrate 7, thereby realizing an integrated touch control function.

As illustrated in FIG. 1a, in some embodiments, the display panel may further include a first insulating layer 8 arranged between the cathode electrode 23 and the touch-sensitive electrode 4, so as to insulate the cathode electrode 23 from the touch-sensitive electrode 4, avoiding an issue of signal crosstalk caused by contact between the cathode electrode 23 and the touch-sensitive electrode 4. Specifically, the cathode electrode 23 may cover the organic light-emitting layers 22 of the plurality of light-emitting units 2, and may cover the pixel definition layer 3 located between the plurality of light-emitting units 2, so as to form an entire-surface common cathode on the display panel. A first through-hole 31 penetrating through the pixel definition layer 3 may be defined at a location of the pixel definition layer 3 matching with the second conductive via 132. The first through-hole 31 may further extend toward a side away from the glass substrate 1 and penetrate through the cathode electrode 23 and the first insulating layer 8, so as to expose a partial surface of the touch-sensitive electrode 4 on a side close to the glass substrate 1. In this way, the second bonding portion 6 may be allowed to extend into the first through-hole 31 and contact the touch-sensitive electrode 4, thereby transmitting the touch-controlling signal between the touch-sensitive electrode 4 and the silicon-based driving substrate 7 through the second bonding portion 6.

Further, the display panel may further include a second insulating layer 9 arranged between the second bonding portion 6 and the cathode electrode 23, so as to insulate the second bonding portion 6 from the cathode electrode 23, avoiding an issue of signal crosstalk caused by contact between the cathode electrode 23 and the second bonding portion 6. Specifically, as illustrated in FIG. 1a and FIG. 1b, FIG. 1b is a sectional view along a A-A line of the display panel in FIG. 1a. The second insulating layer 9 may be arranged inside the first through-hole 31 and surround a peripheral outer side of the second bonding portion 6. That is, the second insulating layer 9 may be annular and may sleeve a portion of the second bonding portion 6 that is in a same layer as the cathode electrode 23, thereby insulating the second bonding portion 6 from the cathode electrode 23.

As illustrated in FIG. 1a, in some embodiments, the conductive via 13 may further include a plurality of third conductive vias 133 arranged around a peripheral outer side of the plurality of first conductive vias 131. The display panel may further include a plurality of third bonding portions 20 arranged on the second surface 12 of the glass substrate 1. Each third bonding portion 20 may be at least partially arranged within the matched third conductive via 133. Each third bonding portion 20 may be electrically connected to the cathode electrode 23 through the matched third conductive via 133, so as to transmit the cathode drive signal to the cathode electrode 23 of the light-emitting unit 2 through the third conductive via 133. The silicon-based driving substrate 7 may further include a plurality of third bonding electrodes 73. Each third bonding electrode 73 may be aligned and bonded with the plurality of third bonding portions 20 in one-to-one correspondence. The silicon-based driving substrate 7 can transmit the cathode drive signal to the cathode electrode 23 through the third bonding electrodes 73 and the third bonding portions 20, so as to control the light-emitting units 2 to emit light.

As illustrated in FIG. 1a, in some embodiments, a distance d between the second conductive via 132 and its adjacent first conductive via 131 may be greater than or equal to 1 micrometer and less than or equal to 1.5 micrometers. Too small a distance between adjacent conductive vias 13 may affect a structural strength of the glass substrate 1, causing damage to the glass substrate 1. Too great a distance may affect a density of the conductive vias 13. Therefore, the distance d between the second conductive via 132 and its adjacent first conductive via 131 may range from 1 micrometer to 1.5 micrometers, so as to ensure the structural strength of the glass substrate 1, while maximizing a density of the conductive vias 13, which is beneficial to increasing a pixel density of the display panel.

In some embodiments, a pore diameter a of the second conductive via 132 may be less than or equal to a pore diameter b of the first conductive via 131, so as to, on the premise of ensuring a sufficient number of the second conductive vias 132, reduce an area proportion of the second conductive via 132 among the conductive vias 13, thereby ensuring that, the first conductive vias 131 may have sufficient size to meet electrical connection requirements. In a case of limited space, to ensure that a circuit board design may meet functional requirements, a size of the first conductive vias 131 for transmitting anode drive signal should be prioritized. This means that, when designing the glass substrate 1, if the space is insufficient to accommodate ideal sizes of all conductive vias 13, the first conductive vias 131 should be ensured to have sufficient size to meet the electrical connection requirements. In contrast, the pore diameter of the second conductive vias 132 for transmitting the touch-controlling signal may be appropriately reduced to save space, as long as a normal use of the touch control function is not affected.

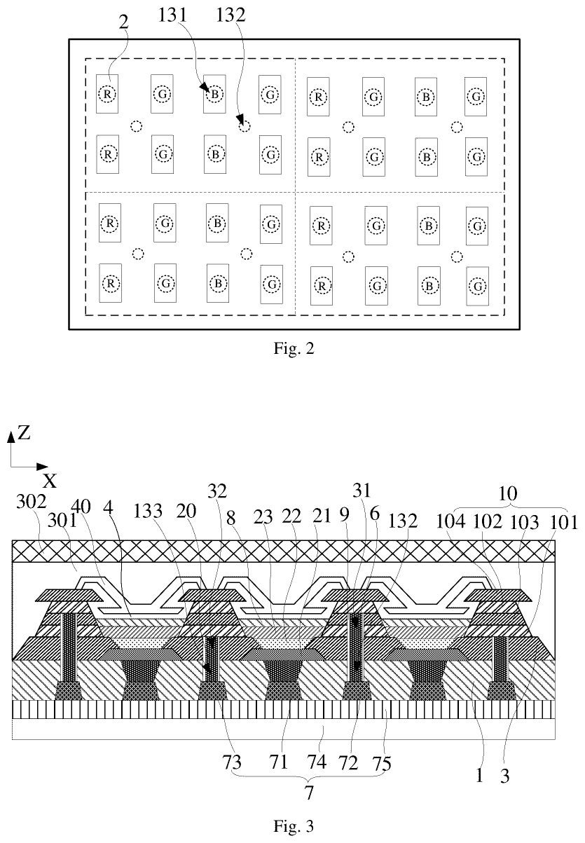

As illustrated in FIG. 2, FIG. 2 is a top view of the display panel in FIG. 1a. In a specific embodiment, the display panel may include a plurality of touch-controlling blocks. A plurality of arrayed light-emitting units 2 may be correspondingly arranged within each touch-controlling block. The plurality of second conductive vias 132 may be arranged within a domain of each touch-controlling block. The number of the plurality of second conductive vias 132 may be set as per the actual needs, which is not limited herein. Specifically, the number of the second conductive vias 132 may be much less than that of the first conductive vias 131, so as to further reduce the area proportion of the second conductive vias 132 in the conductive vias 13, thereby ensuring that, the first conductive vias 131 may have sufficient size to meet electrical connection requirements.

Further, in some embodiments, the plurality of light-emitting units 2 that have the same emission color and are adjacent to a second conductive via 132 may be arranged corresponding to the same first conductive via 131. The silicon-based driving substrate 7 may transmit the cathode drive signal to the plurality of light-emitting units 2 with the same emission color through the first conductive via 131. In this way, the number of first conductive vias 131 required by the display panel may be reduced, thereby effectively increasing the pixel density.

As illustrated in FIG. 1a, in some embodiments, an encapsulation layer 30 may be further arranged on the glass substrate 1. The encapsulation layer 30 may be configured to protect the light-emitting units 2 of the glass substrate 1, isolate external water and oxygen, and prevent the light-emitting units 2 from failing due to water and oxygen intrusion. Specifically, the encapsulation layer 30 may cover a side surface of the cathode electrode 23 away from the anode electrode 21. The encapsulation layer 30 may be engaged on the surface of the glass substrate 1 not covered by the light-emitting units 2.

As illustrated in FIG. 3, FIG. 3 is a schematic structural diagram of a second embodiment of the display panel according to the present disclosure. The structure of the display panel provided in the second embodiment of the present disclosure is basically the same as the structure of the display panel provided in the first embodiment of the present disclosure. The difference may lie in the following that: in the second embodiment of the present disclosure, the display panel may further include an overhanging structure 10. The overhanging structure 10 may be arranged on the pixel definition layer 3 and protrude from the pixel accommodation region. The overhanging structure 10 may be configured to separate sub-pixels of different colors and avoid the issue of pixel crosstalk. Specifically, the overhanging structure 10 may include a first metal layer 101, a third insulating layer 103, and a second metal layer 102 stacked in sequence along a direction from a position close to the glass substrate 1 to another position away from the glass substrate 1.

The cathode electrode 23 may be arranged within the pixel accommodation region. The first insulating layer 8 may be arranged within the pixel accommodation region and cover a surface of the cathode electrode 23. The first metal layer 101 may be arranged on the surface of the pixel definition layer 3 and electrically connected to the silicon-based driving substrate 7. The first metal layer 101 may be in contact with the cathode electrode 23 of the light-emitting unit 2, so as to serve as a common cathode, enabling the silicon-based driving substrate 7 to transmit the cathode drive signal to the cathode electrode 23 through the first metal layer 101. The second metal layer 102 may also be electrically connected to the silicon-based driving substrate 7, and the second metal layer 102 may be in contact with the touch-sensitive electrode 4, so that the silicon-based driving substrate 7 may transmit the touch-controlling signal to the touch-sensitive electrode 4 through the second metal layer 102. The third insulating layer 103 may be arranged between the first metal layer 101 and the second metal layer 102, and may be configured to separate the first metal layer 101 and the second metal layer 102, so that the first metal layer 101 and the second metal layer 102 may be insulated from each other to avoid the issue of signal crosstalk.

The second metal layer 102 may be electrically connected to the second bonding portion 6 through the matched second conductive via 132, thereby achieving an electrical connection with the silicon-based driving substrate 7 through the second bonding portion 6. Specifically, the first through-hole 31 penetrating the pixel definition layer 3 may be defined at a location of the pixel definition layer 3 matching with the second conductive via 132. The first through-hole 31 may further extend towards a side away from the glass substrate 1 to the surface of the second metal layer 102, and may penetrate the first metal layer 101 and the third insulating layer 103. A partial surface of the second metal layer 102 on a side close to the glass substrate 1 may be exposed. In this way, the second bonding portion 6 may be allowed to extend into the first through-hole 31 and contact the second metal layer 102, so as to transmit the touch-controlling signal between the touch-sensitive electrode 4 and the silicon-based driving substrate 7 through the second metal layer 102 and the second bonding portion 6.

Further, the second insulating layer 9 may also be arranged within the first through-hole 31. The second insulating layer 9 may be arranged between the second bonding portion 6 and the first metal layer 101, so as to insulate the second bonding portion 6 from the first metal layer 101, thereby avoiding the issue of signal crosstalk caused by the contact between the first metal layer 101 and the second bonding portion 6. Specifically, the second insulating layer 9 may be arranged inside the first through-hole 31 and surround the peripheral outer side of the second bonding portion 6. In other words, the second insulating layer 9 may be sleeved on the second bonding portion 6, so as to insulate the second bonding portion 6 from the first metal layer 101.

In some embodiments, the third conductive via 133 may further be arranged between adjacent first conductive vias 131. A projection of the third conductive via 133 onto the glass substrate 1 along the stacking direction may be located within a projection of the pixel definition layer 3 onto the glass substrate 1 along the stacking direction Z. In this way, the third bonding portion 20 may be enabled to be electrically connected to the first metal layer 101 through the third conductive via 133, and further transmit the cathode drive signal to the cathode electrode 23 through the third bonding portion 20 and the first metal layer 101 of the overhanging structure 10. In this way, an entire-surface uniformity of the cathode electrode 23 may be increased, thereby effectively reducing a voltage drop and avoiding issues of uneven display. The third conductive via 133 may be arranged in a misaligned manner with the second conductive via 132.

Specifically, the second through-hole 32 penetrating the pixel definition layer 3 may be defined at a location of the pixel definition layer 3 matching with the third conductive via 133. A partial surface of the first metal layer 101 on a side close to the glass substrate 1 may be exposed. The third bonding portion 20 may thus be allowed to extend into the second through-hole 32 and contact the first metal layer 101. The silicon-based driving substrate 7 may be enabled to transmit the cathode drive signal to the cathode electrode 23 through the third bonding electrode 20 and the first metal layer 101.

As illustrated in FIG. 3, in some embodiments, the overhanging structure 10 may further include a fourth insulating layer 104. The fourth insulating layer 104 may be arranged on a side surface of the second metal layer 102 away from the first insulating layer 8. The fourth insulating layer 104 may shield the second metal layer 102. A projection of the fourth insulating layer 104 onto the glass substrate 1 along the stacking direction Z may completely cover a projection of the second metal layer 102 onto the glass substrate 1 along the stacking direction Z. Specifically, in a first direction X perpendicular to the stacking direction Z, both sides of the fourth insulating layer 104 may protrude from the second metal layer 102 to form an eave structure, so that when evaporating and depositing the organic light-emitting layer 22 and the cathode electrode 23, an evaporation angle may be changed by the eave structure, thereby enabling the cathode electrode 23 to engage the first metal layer 101 and completely cover the organic light-emitting layer 22. The first metal layer 101 may be separated from the organic light-emitting layer 22, and insulation between the first metal layer 101 and the organic light-emitting layer 22 may be ensured.

In some embodiments, the display panel may further include an etch protective layer 40. The etch protective layer 40 may be configured to provide, during a preparation process of light-emitting units 2 of another color of the display panel, anti-etch protection for the light-emitting unit 2, thereby avoiding damage to the prepared light-emitting units 2 during subsequent preparation processes. Specifically, the etch protective layer 40 may be arranged on a side of the cathode electrode 23 facing away the organic light-emitting layer 22, and may cover the surface of the cathode electrode 23. An end of the etch protective layer 40 may be engaged on the fourth insulating layer 104, so as to provide the anti-etch protection for various film layers of the light-emitting unit 2. The etch protective layer 40 may include a non-conductive inorganic material. Specifically, the etch protective layer 40 may include a silicon-containing inorganic material, such as a SiNx-based inorganic material.

As illustrated in FIG. 3, the encapsulation layer 30 may include a first encapsulation layer 301 and a second encapsulation layer 302. After all the light-emitting units 2 are prepared, the first encapsulation layer 301 and the second encapsulation layer 302 may be arranged on the display panel to integrally encapsulate the display panel. Specifically, the first encapsulation layer 301 may overlie a side of the etch protective layer 40 away from the glass substrate 1, the second encapsulation layer 302 may overlie a side of the first encapsulation layer 301 away from the glass substrate 1. The first encapsulation layer 301 may be an organic encapsulation layer, and the second encapsulation layer 302 may be an inorganic encapsulation layer.

The present disclosure provides the display panel. The display panel may include the glass substrate 1, the pixel definition layer 3, the plurality of light-emitting units 2, the touch-sensitive electrode 4, the plurality of first bonding portion 5, the plurality of second bonding portion 6, and the silicon-based driving substrate 7. The glass substrate 1 may include the first surface 11 and the second surface 12 that are opposite to each other. The glass substrate 1 may define the plurality of conductive vias 13 extending from the first surface 11 to the second surface 12. The plurality of conductive vias 13 may include the plurality of first conductive vias 131 and the plurality of second conductive vias 132. The pixel definition layer 3 may be arranged on the first surface 11 of the glass substrate 1. The pixel definition layer 3 may protrude from the glass substrate 1 and enclose to form the pixel accommodation region. The plurality of light-emitting units 2 may be arranged within the pixel accommodation regions. Each light-emitting unit 2 may include the anode electrode 21, the organic light-emitting layer 22, and the cathode electrode 23 that are stacked in sequence in a direction away from the glass substrate 1. The touch-sensitive electrode 4 may cover the plurality of light-emitting units 2 and the pixel definition layer 3. Each first bonding portion 5 may be arranged in the matched first conductive via 131. The first bonding portion 5 may be electrically connected to the matched anode electrode 21 through the matched first conductive via 131. Each second bonding portion 6 may be arranged within the matched second conductive via 132. The second bonding portion 6 may be electrically connected to the touch-sensitive electrode 4 through the matched second conductive via 132. The silicon-based driving substrate 7 may be arranged on one side of the second surface 12 of the glass substrate 1. The silicon-based driving substrate 7 may include the plurality of first bonding electrodes 71 and the plurality of second bonding electrodes 72. The plurality of first bonding electrodes 71 may be aligned and bonded with the plurality of first bonding portions 5 in one-to-one correspondence. The plurality of second bonding electrodes 72 may be aligned and bonded with the plurality of second bonding portions 6 in one-to-one correspondence. The projection of the second conductive via 132 onto the glass substrate 1 along the stacking direction of the display panel may be located within the projection of the pixel definition layer 3 onto the glass substrate 1 along the stacking direction. By arranging the light-emitting units 2 and the first bonding portions 5 on the two opposite surfaces of the glass substrate 1 respectively, the plurality of first bonding portions 5 may be in contact and electrically connected to the anode electrodes 21 of the matched light-emitting units 2 through the conductive vias 131. After the first bonding portions 5 are bonded to the first bonding electrode 71 of the silicon-based driving substrate 7, the electrical coupling between the light-emitting units 2 and the silicon-based driving substrate 7 may be achieved, enabling the silicon-based driving substrate 7 to drive the light-emitting units 2 to emit light. In this way, the light-emitting units 2 may be fabricated on the glass substrate 1 and then bonded to the silicon-based driving substrate 7. There is no need to directly fabricate the light-emitting units 2 on the silicon-based driving substrate 7, the problem of reduced product yield caused by damage to the pixel driving circuit 75 due to directly fabrication of the light-emitting units 2 on the silicon-based driving substrate 7 may be avoided. By covering the light-emitting unit 2 with the touch-sensitive electrode 4 and arranging the second conductive vias 132 at locations of the glass substrate 1 matching with the pixel definition layer 3, the plurality of second bonding portions 6 may be respectively electrically connected to the matched touch-sensitive electrodes 4 through the second conductive vias 132. After the second bonding portions 6 are bonded to the second bonding electrodes 72, electrical coupling between the touch-sensitive electrodes 4 and the silicon-based driving substrate 7 may be achieved, thereby enabling the touch-sensitive electrodes 4 to transmit the touch-controlling signal to and from the silicon-based driving substrate 7, thereby realizing the integrated touch control function.

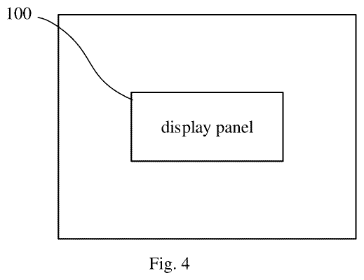

As illustrated in FIG. 4, FIG. 4 is a schematic structural diagram of a display apparatus according to an embodiment of the present disclosure. The present disclosure may further provide the display apparatus. The display apparatus may be configured to display an image. The display apparatus may include the display panel 100 referred to in any of the above-mentioned embodiments. The display apparatus may avoid the problem that fabricating the light-emitting units 2 directly on the silicon-based driving substrate 7 causes damage to the pixel driving circuits 75, leading to a decrease in the product yield. The integrated touch control function may be further realized.

The above are only implementations of the present disclosure, and do not limit the patent scope of the present disclosure. Any equivalent changes to the structure or processes made by the description and drawings of the present disclosure or directly or indirectly used in other related technical field are included in the protection scope of the present disclosure.

1. A display panel, comprising:
a glass substrate, comprising a first surface and a second surface that are opposite to each other, wherein the glass substrate comprises a plurality of conductive vias extending from the first surface to the second surface; the plurality of conductive vias comprise a plurality of first conductive vias and a plurality of second conductive vias;
a pixel definition layer, arranged on the first surface of the glass substrate; wherein the pixel definition layer protrudes from the glass substrate and encloses to form pixel accommodation regions;
a plurality of light-emitting units, arranged within the pixel accommodation regions; wherein each of the plurality of the light-emitting units comprises an anode electrode, an organic light-emitting layer, and a cathode electrode that are stacked in sequence in a direction away from the glass substrate;
a touch-sensitive electrode, configured to cover the plurality of light-emitting units and the pixel definition layer;
a plurality of first bonding portions, wherein each of the plurality of first bonding portions is arranged in a matched first conductive via; each of the plurality of first bonding portions is electrically connected to a matched anode electrode through the matched first conductive via;
a plurality of second bonding portions, wherein each of the plurality of second bonding portions is arranged in a matched second conductive via; each of the plurality of the second bonding portions is electrically connected to the touch-sensitive electrode through the matched second conductive via; and
a silicon-based driving substrate, arranged on one side of the second surface of the glass substrate, comprising a plurality of first bonding electrodes and a plurality of second bonding electrodes; wherein the plurality of first bonding electrodes are aligned and bonded with the plurality of first bonding portions in one-to-one correspondence; the plurality of second bonding electrodes are aligned and bonded with the plurality of second bonding portions in one-to-one correspondence;
wherein a projection of each of the plurality of second conductive via onto the glass substrate along a stacking direction of the display panel is located within a projection of the pixel definition layer onto the glass substrate along the stacking direction.

2. The display panel as claimed in claim 1, wherein
the cathode electrode covers the pixel definition layer;
each of the plurality of the light-emitting units further comprises a first insulating layer; the first insulating layer is arranged between the cathode electrode and the touch-sensitive electrode; the pixel definition layer defines a first through-hole at a location matching with the second conductive via; the first through-hole extends toward a side away from the glass substrate, and penetrates the cathode electrode and the first insulating layer; the first through-hole exposes a partial surface of the touch-sensitive electrode on a side close to the glass substrate; the second bonding portion extends into the first through-hole and is arranged in contact with the touch-sensitive electrode.

3. The display panel as claimed in claim 2, wherein
the display panel further comprising a second insulating layer; the second insulating layer is arranged within the first through-hole and is between the second bonding portion and the cathode electrode; the second insulating layer is arranged around a peripheral outer side of the second bonding portion to insulate the second bonding portion from the cathode electrode.

4. The display panel as claimed in claim 1, wherein
the display panel further comprises an overhanging structure, the overhanging structure is arranged on the pixel definition layer and protrudes from the pixel accommodation regions; the overhanging structure comprises a first metal layer, a third insulating layer, and a second metal layer stacked in sequence along a direction from a position close to the glass substrate to another position away from the glass substrate; the first metal layer is arranged in contact with the cathode electrode, and the second metal layer is arranged in contact with the touch-sensitive electrode; the second metal layer is electrically connected to the second bonding portion through the matched second conductive via.

5. The display panel as claimed in claim 4, wherein
the cathode electrode is arranged within the pixel accommodation region; the pixel definition layer defines a first through-hole at a location matching with the second conductive via; the first through-hole extends toward a side away from the glass substrate and penetrates the first metal layer and the third insulating layer; the first through-hole exposes a partial surface of the second metal layer on a side close to the glass substrate; the second bonding portion extends into the first through-hole and is arranged in contact with the second metal layer.

6. The display panel as claimed in claim 5, wherein
a second insulating layer is further arranged within the first through-hole; the second insulating layer is arranged between the second bonding portion and the first metal layer; and, the second insulating layer is arranged around a peripheral outer side of the second bonding portion to insulate the second bonding portion from the first metal layer.

7. The display panel as claimed in claim 1, wherein
the conductive vias further comprise a plurality of third conductive vias; the plurality of third conductive vias are arranged around the plurality of first conductive vias; the display panel further comprises a plurality of third bonding portions arranged on the second surface of the glass substrate; the third bonding portion is electrically connected to the cathode electrode through a matched third conductive via; the silicon-based driving substrate further comprises a plurality of third bonding electrodes; the plurality of third bonding electrodes are aligned and bonded with the plurality of third bonding portions in one-to-one correspondence; or
the third conductive via is arranged between adjacent first conductive vias, a projection of the third conductive via onto the glass substrate along the stacking direction is located within a projection of the pixel definition layer onto the glass substrate along the stacking direction.

8. The display panel as claimed in claim 1, wherein
a pore diameter of the second conductive via is less than or equal to a pore diameter of the first conductive via.

9. The display panel as claimed in claim 1, wherein
a distance between the second conductive via and its adjacent first conductive via is greater than or equal to 1 micrometer and less than or equal to 1.5 micrometers.

10. The display panel as claimed in claim 1, wherein
the display panel further comprises an encapsulation layer; the encapsulation layer is arranged on the glass substrate, and cover a side surface of the cathode electrode away from the anode electrode.

11. A display apparatus comprising a display panel, wherein
the display panel comprises:
a glass substrate, comprising a first surface and a second surface that are opposite to each other, wherein the glass substrate comprises a plurality of conductive vias extending from the first surface to the second surface; the plurality of conductive vias comprise a plurality of first conductive vias and a plurality of second conductive vias;
a pixel definition layer, arranged on the first surface of the glass substrate; wherein the pixel definition layer protrudes from the glass substrate and encloses to form pixel accommodation regions;
a plurality of light-emitting units, arranged within the pixel accommodation regions; wherein each of the plurality of the light-emitting units comprises an anode electrode, an organic light-emitting layer, and a cathode electrode that are stacked in sequence in a direction away from the glass substrate;
a touch-sensitive electrode, configured to cover the plurality of light-emitting units and the pixel definition layer;
a plurality of first bonding portions, wherein each of the plurality of first bonding portions is arranged in a matched first conductive via; each of the plurality of first bonding portions is electrically connected to a matched anode electrode through the matched first conductive via;
a plurality of second bonding portions, wherein each of the plurality of second bonding portions is arranged in a matched second conductive via; each of the plurality of the second bonding portions is electrically connected to the touch-sensitive electrode through the matched second conductive via; and
a silicon-based driving substrate, arranged on one side of the second surface of the glass substrate, comprising a plurality of first bonding electrodes and a plurality of second bonding electrodes; wherein the plurality of first bonding electrodes are aligned and bonded with the plurality of first bonding portions in one-to-one correspondence; the plurality of second bonding electrodes are aligned and bonded with the plurality of second bonding portions in one-to-one correspondence;
wherein a projection of each of the plurality of second conductive via onto the glass substrate along a stacking direction of the display panel is located within a projection of the pixel definition layer onto the glass substrate along the stacking direction.

12. The display apparatus as claimed in claim 11, wherein
the cathode electrode covers the pixel definition layer;
each of the plurality of the light-emitting units further comprises a first insulating layer; the first insulating layer is arranged between the cathode electrode and the touch-sensitive electrode; the pixel definition layer defines a first through-hole at a location matching with the second conductive via; the first through-hole extends toward a side away from the glass substrate, and penetrates the cathode electrode and the first insulating layer; the first through-hole exposes a partial surface of the touch-sensitive electrode on a side close to the glass substrate; the second bonding portion extends into the first through-hole and is arranged in contact with the touch-sensitive electrode.

13. The display apparatus as claimed in claim 12, wherein
the display panel further comprising a second insulating layer; the second insulating layer is arranged within the first through-hole and is between the second bonding portion and the cathode electrode; the second insulating layer is arranged around a peripheral outer side of the second bonding portion to insulate the second bonding portion from the cathode electrode.

14. The display apparatus as claimed in claim 11, wherein
the display panel further comprises an overhanging structure, the overhanging structure is arranged on the pixel definition layer and protrudes from the pixel accommodation regions; the overhanging structure comprises a first metal layer, a third insulating layer, and a second metal layer stacked in sequence along a direction from a position close to the glass substrate to another position away from the glass substrate; the first metal layer is arranged in contact with the cathode electrode, and the second metal layer is arranged in contact with the touch-sensitive electrode; the second metal layer is electrically connected to the second bonding portion through the matched second conductive via.

15. The display apparatus as claimed in claim 14, wherein
the cathode electrode is arranged within the pixel accommodation region; the pixel definition layer defines a first through-hole at a location matching with the second conductive via; the first through-hole extends toward a side away from the glass substrate and penetrates the first metal layer and the third insulating layer; the first through-hole exposes a partial surface of the second metal layer on a side close to the glass substrate; the second bonding portion extends into the first through-hole and is arranged in contact with the second metal layer.

16. The display apparatus as claimed in claim 15, wherein
a second insulating layer is further arranged within the first through-hole; the second insulating layer is arranged between the second bonding portion and the first metal layer; and, the second insulating layer is arranged around a peripheral outer side of the second bonding portion to insulate the second bonding portion from the first metal layer.

17. The display apparatus as claimed in claim 11, wherein
the conductive vias further comprise a plurality of third conductive vias; the plurality of third conductive vias are arranged around the plurality of first conductive vias; the display panel further comprises a plurality of third bonding portions arranged on the second surface of the glass substrate;
the third bonding portion is electrically connected to the cathode electrode through a matched third conductive via; the silicon-based driving substrate further comprises a plurality of third bonding electrodes; the plurality of third bonding electrodes are aligned and bonded with the plurality of third bonding portions in one-to-one correspondence; or
the third conductive via is arranged between adjacent first conductive vias, a projection of the third conductive via onto the glass substrate along the stacking direction is located within a projection of the pixel definition layer onto the glass substrate along the stacking direction.

18. The display apparatus as claimed in claim 11, wherein
a pore diameter of the second conductive via is less than or equal to a pore diameter of the first conductive via.

19. The display apparatus as claimed in claim 11, wherein
a distance between the second conductive via and its adjacent first conductive via is greater than or equal to 1 micrometer and less than or equal to 1.5 micrometers.

20. The display apparatus as claimed in claim 11, wherein
the display panel further comprises an encapsulation layer; the encapsulation layer is arranged on the glass substrate, and cover a side surface of the cathode electrode away from the anode electrode.
